(19) United States
(12) Patent Application Publication
(10) Pub. No.: US 2026/0322073 A1
(43) Pub. Date: Oct. 15, 2026

(54) SINGLE-MODE HIGH-POWER VERTICAL-CAVITY SURFACE-EMITTING LASER STRUCTURE AND FABRICATION METHOD THEREOF

(71) Applicant: Shenzhen Technology University, Shenzhen City (CN)

(72) Inventors: Hui LI, Shenzhen City (CN); Jian FENG, Shenzhen City (CN); Zhenhuan QIU, Shenzhen City (CN); Jincong XIE, Shenzhen City (CN); Bin WANG, Shenzhen City (CN); Ke ZHANG, Shenzhen City (CN); Cunzheng NING, Shenzhen City (CN); Chuyu ZHONG, Shenzhen City (CN); Jinlong LU, Shenzhen City (CN); Shihao DING, Shenzhen City (CN); Shupeng DENG, Shenzhen City (CN); Nannan LI, Shenzhen City (CN)

(21) Appl. No.: 19/457,534

(22) Filed: Jan. 23, 2026

(30) Foreign Application Priority Data
Jan. 24, 2025 (CN) 202510113408.8

(51) Int. Cl. H01S 5/183; H01S 5/042

(52) U.S. Cl. CPC H01S 5/18341; H01S 5/04252; H01S 5/04257; H01S 5/18369

(57) ABSTRACT

A single-mode high-power vertical-cavity surface-emitting laser (VCSEL) structure and its fabrication method are provided. The laser includes: from bottom to top in sequence, a substrate layer, a lower N-type distributed Bragg reflector (DBR), an active region, an asymmetric oxidation confinement layer, a space layer, an upper P-type DBR, and a surface relief structure; the substrate layer and the lower N-type DBR constitute a first oblique elliptical cylinder; the active region, the asymmetric oxidation confinement layer, and the space layer constitute a second oblique elliptical cylinder; the upper P-type DBR and the surface relief structure constitute a third oblique elliptical cylinder; negative electrodes are disposed at both ends of the major axis of the first oblique elliptical cylinder; positive electrodes are disposed at both ends of the minor axis of the second oblique elliptical cylinder; and the negative electrodes and the positive electrodes constitute an intra-cavity asymmetric electrode structure.

### CROSS-REFERENCE TO RELATED APPLICATIONS

This application claims priority to Chinese Patent Application No. 202510113408.8, filed on Jan. 24, 2025, the contents of which are hereby incorporated by reference.

### TECHNICAL FIELD

The present disclosure belongs to the technical field of semiconductor lasers, and particularly relates to a single-mode high-power vertical-cavity surface-emitting laser (VCSEL) structure and a fabrication method thereof.

### BACKGROUND

As an emerging semiconductor laser technology, the vertical-cavity surface-emitting laser (VCSEL) has demonstrated significant advantages in multiple fields. With its characteristics of compact structure, low power consumption, fast modulation speed, and high cost-effectiveness, VCSELs have been widely used in optical communications, sensors, three-dimensional (3D) sensing technologies such as facial recognition, optical interconnects, and lidar. Compared with conventional edge-emitting lasers, the unique feature of VCSELs lies in their ability to emit light beams perpendicular to the substrate, which makes them easier to couple with optical fibers and suitable for array applications, thereby playing a key role in integrated optical systems.

Despite the above advantages of VCSEL technology, there remain some technical challenges in existing designs. Particularly in terms of mode control, polarization stability, and beam quality, conventional VCSEL designs face certain limitations. In the current injection region, the non-uniform distribution of current and the optical field around the active layer is a primary cause leading to reduced laser efficiency, mode instability, and an increased beam divergence angle. To address these issues, oxidation confinement layer technology is widely adopted. By oxidizing high-aluminum-content materials such as aluminum gallium arsenide (AlGaAs) to form a lateral confinement structure, the distribution of current and the optical field may be effectively controlled, thereby enhancing VCSEL efficiency.

However, existing oxidation confinement layers typically employ symmetrical circular or elliptical structures. In specific application scenarios, these symmetrical structures still may not fully meet the requirements for performance optimization. Especially when increasing the modulation bandwidth and reducing the oxidation aperture to improve VCSEL speed, challenges related to optical loss and thermal management are encountered.

### SUMMARY

To solve the above-mentioned technical problems, the present disclosure proposes a single-mode high-power vertical-cavity surface-emitting laser (VCSEL) structure and a fabrication method thereof, so as to solve the problems existing in the prior art described above.

To achieve the above objectives, in a first aspect, the present disclosure provides a single-mode high-power vertical-cavity surface-emitting laser structure, including:
from bottom to top in sequence: a substrate layer, a lower N-type distributed Bragg reflector (DBR), an active region, an asymmetric oxidation confinement layer, a space layer, an upper P-type DBR, and a surface relief structure;
where the substrate layer and the lower N-type DBR constitute a first oblique elliptical cylinder; the active region, the asymmetric oxidation confinement layer, and the space layer constitute a second oblique elliptical cylinder; and the upper P-type DBR and the surface relief structure constitute a third oblique elliptical cylinder; and
negative electrodes are disposed at both ends of a major axis of the first oblique elliptical cylinder; positive electrodes are disposed at both ends of a minor axis of the second oblique elliptical cylinder; and the negative electrode and the positive electrode constitute an intra-cavity asymmetric electrode structure.

Optionally, the first oblique elliptical cylinder, the second oblique elliptical cylinder, and the third oblique elliptical cylinder are each formed by combining two ellipses having identical minor axes and different major axes, and are designed as coaxial elliptical cylinders.

Optionally, the asymmetric oxidation confinement layer is formed by combining two ellipses having identical minor axes and different major axes.

Optionally, the space layer is modulation-doped to optimize parasitic resistance.

Optionally, the active region includes multiple active regions, each of the multiple active regions is formed by alternately stacking multiple pairs of quantum wells and barriers.

Optionally, the surface relief structure is formed by depositing and etching on top of the laser structure.

Optionally, the intra-cavity asymmetric electrode employs asymmetric current injection.

Optionally, a material of the intra-cavity asymmetric electrode is titanium (Ti) or platinum (Pt).

In a second aspect, the present disclosure also provides a method for fabricating a single-mode high-power vertical-cavity surface-emitting laser structure, including the following steps:
epitaxially growing the lower N-type DBR on a substrate layer from bottom to top by molecular beam epitaxy (MBE) or metal-organic chemical vapor deposition (MOCVD), to constitute the first oblique elliptical cylinder;
epitaxially growing the active region and the oxidation confinement layer on the first oblique elliptical cylinder, to form the asymmetric oxidation confinement layer, epitaxially growing the space layer, and constituting the second oblique elliptical cylinder;
continuing to epitaxially grow the third oblique elliptical cylinder, including the upper P-type DBR;
depositing the negative electrode at both ends of the major axis of the first oblique elliptical cylinder, and depositing the positive electrode at both ends of the minor axis of the second oblique elliptical cylinder, to constitute the intra-cavity asymmetric electrode; and
depositing and etching the relief structure on the top of the laser structure.

Compared with the prior art, the present disclosure has the following advantages and technical effects.

The present disclosure provides a single-mode high-power vertical-cavity surface-emitting laser structure, including: from bottom to top in sequence, a substrate layer, a lower N-type DBR, an active region, an asymmetric oxidation confinement layer, a space layer, an upper P-type DBR, and a surface relief structure; where the substrate layer and the lower N-type DBR constitute a first oblique elliptical cylinder; the active region, the asymmetric oxidation confinement layer, and the space layer constitute a second oblique elliptical cylinder; the upper P-type DBR and the surface relief structure constitute a third oblique elliptical cylinder; negative electrodes are disposed at both ends of the major axis of the first oblique elliptical cylinder; positive electrodes are disposed at both ends of the minor axis of the second oblique elliptical cylinder; and the negative electrode and the positive electrode constitute an intra-cavity asymmetric electrode structure.

The present disclosure adopts an oblique elliptical mesa design with an asymmetric oxidation confinement layer, arranges a space layer near the active region, enables the use of an all-semiconductor intra-cavity asymmetric electrode structure while optimizing current injection, and simultaneously introduces a relief structure at the light-emitting output of the upper DBR. The asymmetric oblique elliptical oxidation confinement layer effectively achieves precise control of current injection and the optical field, suppresses the excitation of higher-order modes, enhances mode coupling effects, and significantly improves the modulation characteristics, single-mode stability, and output efficiency of the device. Furthermore, this design optimizes the heat dissipation performance of the device, contributing to improved operational stability under high power. By providing the space layer, the cavity length may be precisely controlled to achieve stable control of the emission wavelength and enhance the heat dissipation and thermal management performance of the device. By combining the design of an elliptical multi-mesa intra-cavity electrode and employing asymmetric current injection, the heat dissipation capability, carrier recombination efficiency, and mode stability of the device are improved.

The present disclosure increases the single-mode output power through the relief structure. By improving the coupling efficiency of the light beam, it significantly reduces reflection loss, increases the optical output power and overall coupling efficiency, demonstrating excellent performance, particularly in fiber coupling applications. Through the integrated structure composed of the oblique elliptical mesa, the relief structure, and the intra-cavity asymmetric electrode, single-mode high power of the device is achieved.

### BRIEF DESCRIPTION OF THE DRAWINGS

The drawings constituting a part of this disclosure are used to provide further understanding of this disclosure. The schematic embodiments and descriptions of this disclosure are used to explain this disclosure and do not constitute an improper limitation of this disclosure. In the drawings:

FIG. 1 is a cross-sectional view of the device structure according to an embodiment of the present disclosure.

FIG. 2 is a top view of the device structure according to an embodiment of the present disclosure.

FIG. 3 is the flowchart of a method for fabricating a single-mode high-power vertical-cavity surface-emitting laser structure according to an embodiment of the present disclosure.

### DETAILED DESCRIPTION OF THE EMBODIMENTS

It should be noted that, in the case of no conflict, the embodiments in this disclosure and the features in the embodiments may be combined with each other. This disclosure will be described in detail below with reference to the accompanying drawings and in combination with the embodiments.

It should be noted that the steps illustrated in the flowchart of the accompanying drawings may be executed in a computer system such as a set of computer-executable instructions. Although a logical order is shown in the flowchart, in some cases, the steps shown or described may be executed in an order different from the order herein.

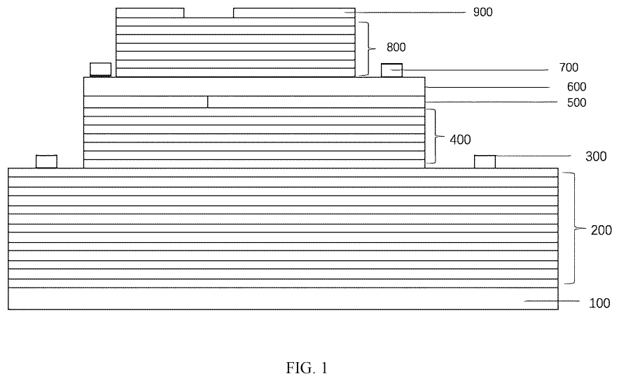

As shown in FIG. 1, this embodiment provides a single-mode high-power vertical-cavity surface-emitting laser (VCSEL) structure, including:
from bottom to top in sequence: a first oblique elliptical mesa including a gallium arsenide (GaAs) substrate 100, a lower N-type distributed Bragg reflector (DBR) 200, and negative electrodes 300 distributed on the first elliptical mesa; a second oblique elliptical mesa including an active region 400, an asymmetric oxidation confinement layer 500, a space layer 600, and positive electrodes 700 distributed on the second oblique elliptical mesa; a third oblique elliptical mesa including an upper P-type DBR 800 and a surface relief structure 900 formed by etching. The space layer 600 is located at the top of the active region 400. The intra-cavity asymmetric electrode is composed of the negative electrodes 300 distributed on the first oblique elliptical mesa and the positive electrodes 700 distributed on the second oblique elliptical mesa. The electron-injected negative electrodes are disposed at both ends of the major axis of the elliptical mesa of the lower N-type DBR 200, and the electron hole-injected positive electrodes are disposed at both ends of the minor axis within the space layer of the second oblique elliptical mesa. This structure improves the single-mode stability, output efficiency, and overall coupling efficiency of the device, optimizes the heat dissipation performance of the device, and achieves stable control of the emission wavelength.

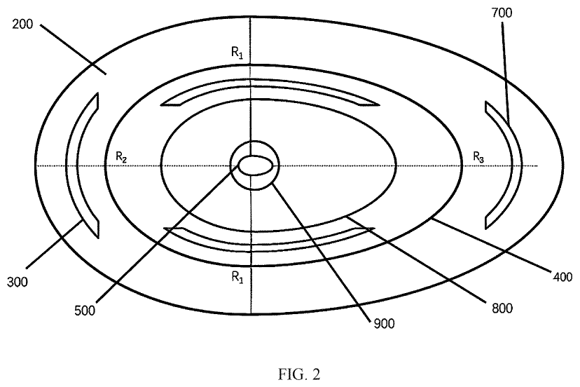

FIG. 2 is a schematic top view in this embodiment. As an innovative implementation, the overall structure of the device is an oblique elliptical multi-mesa structure. The substrate 100 and the lower N-type DBR 200 constitute a first oblique elliptical cylinder. The first oblique elliptical mesa is formed by splicing two semi-elliptical mesas: one with a minor axis of R₁ and a major axis of R₂, and the other with a minor axis of R₁ and a major axis of R₃.

The active region 400, the oxidation confinement layer 500, and the space layer 600 together constitute a second oblique elliptical cylinder. The second oblique elliptical cylinder is also formed by splicing semi-elliptical mesas having identical minor axes and different major axes. The third elliptical mesa is formed by the upper P-type DBR 800 and the surface relief structure 900 together. The first oblique elliptical cylinder, the second oblique elliptical cylinder, and the third oblique elliptical cylinder are designed as coaxial elliptical cylinders. This structure optimizes the heat dissipation capability of the device. The shaded portions on the first elliptical mesa represent the negative electrode 300, and the shaded portions on the second elliptical mesa represent the positive electrode 700.

As an innovative implementation, the surface relief structure 900 is used to enhance the optical coupling efficiency of the device. The non-elliptical multi-mesa and the intra-cavity asymmetric electrode employ asymmetric current injection, which improves the heat dissipation capability, carrier recombination efficiency, and mode stability of the device.

Specifically, the active region includes multiple active regions, being greater than or equal to 2, and is not limited to 3, 4, 5, etc. Each active region is formed by alternately stacking multiple pairs of quantum wells and barriers.

As an additional implementation, the laser structure includes specific photolithography and wet oxidation techniques after epitaxial growth to form the oblique elliptical mesa with asymmetric oxidation confinement. The oblique elliptical mesa is formed by combining two ellipses having identical minor axes and different major axes. Compared with the symmetrical elliptical oxidation confinement layer, the oblique elliptical oxidation confinement layer may more effectively achieve current injection and precise control of the optical field. Simultaneously, adjusting to an appropriate oblique elliptical oxidation aperture may significantly impact the single-mode stability and output efficiency of the device. Furthermore, this design may compensate for the insufficient heat dissipation performance of symmetrical elliptical oxidation confinement layer mesas, contributing to improved operational stability under high power.

As an additional implementation, by providing the space layer on the oxidation layer and modulation-doping the space layer, the parasitic resistance is optimized and the parasitic cutoff frequency is increased. By combining the design of the oblique elliptical multi-mesa intra-cavity electrode and employing asymmetric current injection, the phenomenon of carrier congestion is reduced, allowing the injected holes and electrons to recombine effectively and ensuring uniform current distribution. Consequently, more current is injected into the active region, thereby improving the luminous efficiency and optical output power of the device. This also enhances the heat dissipation capability and polarization stability of the device, favoring the polarization of emitted light in the direction perpendicular to the current. The heat dissipation capability, carrier recombination efficiency, and mode stability of the device are improved. Forming the relief structure by deposition and etching on the upper DBR may increase the single-mode optical output power and improve the coupling efficiency of the light beam, thereby increasing the overall coupling efficiency.

In summary, this embodiment proposes a VCSEL laser structure. The structure is fabricated by etching and oxidation after epitaxial growth to create an elliptical mesa with asymmetric oxidation confinement, followed by continued epitaxial growth of a space layer; it is then integrated with oblique elliptical multi-mesa intra-cavity electrodes, epitaxial growth of an upper DBR, and deposition and etching of a relief structure. The purpose is to utilize the oblique elliptical mesa with asymmetric oxidation confinement to improve the effective current injection efficiency of the device and achieve further control of the optical field, while enhancing the single-mode stability of the device. The thickness and refractive index of the space layer are utilized to achieve effective control of the cavity length, thereby further effectively controlling the output wavelength of the device. By combining the design of the oblique elliptical multi-mesa intra-cavity electrode and employing asymmetric current injection, the heat dissipation capability, carrier recombination efficiency, and mode stability of the device are improved. The relief structure formed by etching is used to enhance the optical coupling efficiency of the device, thereby improving the overall performance of the device.

Beneficial effects of this embodiment:
this embodiment discloses a single-mode high-power vertical-cavity surface-emitting laser structure. The purpose is to utilize the asymmetric oxidation confinement layer, the epitaxially formed space layer, the elliptical multi-mesa intra-cavity asymmetric electrodes, and the relief structure etched and grown on the P-type upper DBR, to improve the current injection efficiency, optical coupling efficiency, single-mode stability, and controllability of the output wavelength of the device. This enhances the temperature performance and thermal management of the device under high power, thereby optimizing the overall performance of the laser.

### Embodiment 2

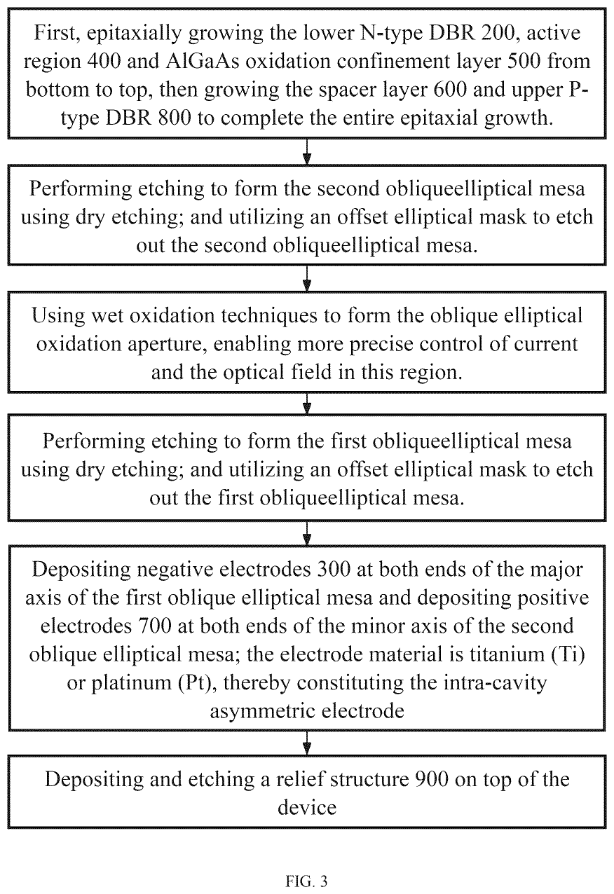

As shown in FIG. 3, this embodiment provides a method for fabricating a single-mode high-power vertical-cavity surface-emitting laser structure, including:
S1, on a GaAs substrate 100, epitaxially growing a lower N-type DBR 200 from bottom top sequentially via molecular beam epitaxy (MBE) or metal-organic chemical vapor deposition (MOCVD) technology, and then performing etching to form a first oblique elliptical mesa.

The specific method involves using dry etching. Based on the anisotropy of the material′ etching rates in different directions, the direction with a faster etching rate is designed as the minor axis of the ellipse, and the direction with a slower etching rate is designed as part of the major axis of the ellipse, enabling the etched aperture to achieve a favorable circular mode.
S2, epitaxially growing an active region 400 and an AlGaAs oxidation confinement layer 500 on the first elliptical mesa, and performing oxidation in the same manner to form an oblique elliptical oxidation aperture; subsequently, epitaxially growing a space layer 600 to form the basis of the second oblique elliptical mesa.

The second oblique elliptical mesa is formed by splicing two ellipses having identical minor axes and different major axes, enabling more precise control of current and the optical field in this region. This splicing design may not only further optimize current distribution, ensuring that the current is concentrated in the active region, but also improve the laser mode control, preventing the occurrence of unstable or asymmetrically distributed laser modes.
S3, continuing to epitaxially grow a third-layer oblique elliptical mesa structure, the upper P-type DBR 800, depositing negative electrodes 300 at both ends of the major axis of the first oblique elliptical mesa and depositing positive electrodes 700 at both ends of the minor axis of the second oblique elliptical mesa. The electrode material is titanium (Ti) or platinum (Pt), thereby constituting the intra-cavity asymmetric electrode.

Combined with the oblique elliptical multi-mesa structure, and since the mobility of holes is less than that of electrons, adopting the above electrode structure may stabilize polarization and enable effective recombination of the injected holes and electrons, reduce carrier congestion, ensure uniform current distribution, thereby injecting more current into the active region, and consequently improve the luminous efficiency, optical output power, and mode stability of the device. Simultaneously, through the alternating arrangement of high and low refractive index materials, the upper P-type DBR 800 and the lower N-type DBR 200 together achieve a high reflectivity effect, enhancing optical feedback efficiency and reducing intra-cavity loss.
S4, depositing and etching a relief structure 900 on top of the device.

The introduction of the relief structure increases the single-mode output power, while improving the coupling efficiency of the light beam, thereby increasing the overall optical output power of the device.

Overall, the VCSEL structure of this embodiment, through the two-mesa design, the application of the asymmetric oxidation confinement layer, and the intra-cavity asymmetric electrodes, effectively optimizes current injection, heat dissipation, and mode stability, and increases the single-mode output power. This structure overcomes the thermal effect issues of traditional VCSELs in high-power applications, while significantly enhancing the optical output quality and reliability of the device.

The above are merely optional specific implementations of this disclosure, but the protection scope of this disclosure is not limited thereto. Any person skilled in the art familiar with the technical field may easily conceive of changes or substitutions within the technical scope disclosed in this disclosure, and all such changes or substitutions shall fall within the protection scope of this disclosure. Therefore, the protection scope of this disclosure shall be subject to the protection scope of the claims.

What is claimed is:

1. A single-mode high-power vertical-cavity surface-emitting laser structure, comprising:
from bottom to top in sequence: a substrate layer, a lower N-type distributed Bragg reflector (DBR), an active region, an asymmetric oxidation confinement layer, a space layer, an upper P-type DBR, and a surface relief structure;
wherein the substrate layer and the lower N-type DBR constitute a first oblique elliptical cylinder; the active region, the asymmetric oxidation confinement layer, and the space layer constitute a second oblique elliptical cylinder; and the upper P-type DBR and the surface relief structure constitute a third oblique elliptical cylinder;
negative electrodes are disposed at both ends of a major axis of the first oblique elliptical cylinder; positive electrodes are disposed at both ends of a minor axis of the second oblique elliptical cylinder; and the negative electrodes and the positive electrodes constitute an intra-cavity asymmetric electrode structure;
the first oblique elliptical cylinder, the second oblique elliptical cylinder, and the third oblique elliptical cylinder are each formed by combining two ellipses having identical minor axes and different major axes, and are designed as coaxial elliptical cylinders; and
the asymmetric oxidation confinement layer is formed by combining two ellipses having identical minor axes and different major axes.

2. The laser structure according to claim 1, wherein the space layer is modulation-doped to optimize parasitic resistance.

3. The laser structure according to claim 1, wherein the active region comprises a plurality of active regions, and each of the plurality of active regions is formed by alternately stacking a plurality of pairs of quantum wells and barriers.

4. The laser structure according to claim 1, wherein the surface relief structure is formed by depositing and etching on a top of the laser structure.

5. The laser structure according to claim 1, wherein the intra-cavity asymmetric electrode structure employs asymmetric current injection.

6. The laser structure according to claim 1, wherein a material of the intra-cavity asymmetric electrode structure is titanium (Ti) or platinum (Pt).

7. A method for fabricating the single-mode high-power vertical-cavity surface-emitting laser structure according to claim 1, comprising following steps:
epitaxially growing the lower N-type DBR on the substrate layer from bottom to top by molecular beam epitaxy (MBE) or metal-organic chemical vapor deposition (MOCVD) to constitute the first oblique elliptical cylinder;
epitaxially growing the active region and an oxidation confinement layer on the first oblique elliptical cylinder to form the asymmetric oxidation confinement layer, and epitaxially growing the space layer to constitute the second oblique elliptical cylinder;
continuing to epitaxially grow the third oblique elliptical cylinder, comprising the upper P-type DBR;
depositing the negative electrodes at both ends of the major axis of the first oblique elliptical cylinder, and depositing the positive electrodes at both ends of the minor axis of the second oblique elliptical cylinder to constitute the intra-cavity asymmetric electrode structure; and
depositing and etching the surface relief structure on a top of the laser structure.
